(19) United States
(12) Patent Application Publication
(10) Pub. No.: US 2025/0136435 A1
(43) Pub. Date: May 1, 2025

(54) STRETCHABLE ELECTRICAL INTERCONNECT, FLEXIBLE ELECTRONIC SYSTEM, AND FABRICATION METHOD THEREOF

(71) Applicant: The Hong Kong University of Science and Technology, Hong Kong (CN)

(72) Inventors: Hongyu YU, Hong Kong (CN); Rui JIAO, Hong Kong (CN)

(21) Appl. No.: 18/922,532

(22) Filed: Oct. 22, 2024

Related U.S. Application Data
(60) Provisional application No. 63/593,235, filed on Oct. 25, 2023.

(51) Int. Cl. B81B 7/00; B81C 1/00

(52) U.S. Cl. CPC B81B 7/0006; B81C 1/00142; B81B 2203/0109; B81B 2203/019; B81B 2203/04

(57) ABSTRACT

A stretchable electrical interconnect comprises: a curved wall that is stretchable lengthwise towards two ends of the curved wall, wherein the curved wall has a height that extends perpendicularly to a plane in which the two ends of the curved wall extend, and wherein the two ends of the curved wall are configured to be connectable to one or more electronic devices.

### CROSS-REFERENCE TO RELATED APPLICATION

The present application claims priority from U.S. Provisional Patent Application No. 63/593,235, filed Oct. 25, 2023, the disclosure of which is incorporated by reference herein.

### TECHNICAL FIELD

The present application relates broadly, but not exclusively, to stretchable electrical interconnects, flexible electronic systems, and fabrication methods thereof.

### BACKGROUND

Curved electronics, also referred to as flexible electronic systems in the present application, are advancing rapidly due to their ability to conform to non-flat surfaces, offering flexibility and durability that rigid electronics cannot. These qualities make them ideal for various applications, such as wearables, smart lenses, flexible displays, and soft robotics.

Two main manufacturing methods have emerged: direct fabrication on curved surfaces using techniques like inkjet printing and 3D printing, and transforming 2D devices into curved forms. The latter, though more complex, yields better performance and stretchability, which is crucial for complex surfaces with nonzero Gaussian curvature.

Stretchability can be achieved through either using inherently stretchable materials or by incorporating stretchable structures. The first approach often leads to lower conductivity, while the second involves structural designs like wavy or serpentine shapes that provide flexibility but may introduce mechanical stress. Despite advances, the existing methods still face limitations in long-term performance and industrial scalability.

After fabrication, transforming planar devices into curved forms remains a challenge. Techniques like pre-stretching elastomers or using conformal additive stamping have been proposed but come with drawbacks, such as material fatigue or location distortion. Origami-based methods offer another solution by folding 2D tessellations into 3D shapes, but this approach can result in undesirable angles and restricted application scenarios.

A need therefore exists to provide material and/or structural solutions and manufacturing methods for curved electronics that seek to overcome, or at least minimize, the above-mentioned problems related to stretchability, durability, scalability, and long-term performance in order to fully realize the potential of curved electronics in diverse applications.

### SUMMARY

According to an aspect of the present disclosure, there is provided a stretchable electrical interconnect. The stretchable electrical interconnect comprises a curved wall that is stretchable lengthwise towards two ends of the curved wall, wherein the curved wall has a height that extends perpendicularly to a plane in which the two ends of the curved wall extend, and wherein the two ends of the curved wall are configured to be connectable to one or more electronic devices.

According to another aspect of the present disclosure, there is provided a flexible electronic system. The flexible electronic system comprises one or more electronic devices, and one or more stretchable electrical interconnects connecting the one or more electronic devices, wherein each of the one or more stretchable electrical interconnects comprises: a curved wall that is stretchable lengthwise towards two ends of the curved wall, wherein the curved wall has a height that extends perpendicularly to a plane in which the two ends of the curved wall extend, and wherein the two ends of the curved wall are connected to the one or more electronic devices.

According to yet another aspect of the present disclosure, there is provided a method of fabricating a flexible electronic system, the method comprises providing a silicon wafer, wherein a top surface of the silicon wafer has formed thereon a top oxide layer, and wherein a bottom surface of the silicon wafer has formed thereon a bottom oxide layer; depositing two electrode metal layers with an insulating layer in between onto the top oxide layer of the silicon wafer to form one or more electrodes; patterning and etching the two electrode metal layers, the insulating layer in between, the top oxide layer, and the silicon wafer to form one or more grooves in the silicon wafer; depositing a first layer of polymer, a metal layer and a second layer of polymer successively to fill the one or more grooves to form one or more stretchable electrical interconnects; and bonding one or more electronic devices to the one or more electrodes to form the flexible electronic system in a planar form, wherein each of the stretchable electrical interconnects is a curved wall that is stretchable lengthwise towards two ends of the curved wall, wherein the curved wall has a height that extends perpendicularly to a plane in which the two ends of the curved wall extend, and wherein the two ends of the curved wall are connected to the one or more electronic devices.

### BRIEF DESCRIPTION OF THE DRAWINGS

Embodiments and implementations are provided by way of example only, and will be better understood and readily apparent to one of ordinary skill in the art from the following written description, read in conjunction with the drawings, in which:

FIG. 1 illustrates a schematic diagram 100 depicting an embodiment of a stretchable electrical interconnect 102 according to the present application. FIG. 1 also shows an embodiment of a flexible electronic system 104 according to the present application, which incorporates the stretchable electrical interconnect 102. For simplicity, the flexible electronic system 104 is interchangeably referred to as “curved electronics” in the present disclosure.

FIG. 2 presents a series of images illustrating the embodiment of the stretchable electrical interconnect 102 under varying stretching conditions, ranging from 0% to 4000%. The images demonstrate that the stretchable electrical interconnect 102 retains its structural integrity under significant elongation.

FIG. 3 provides a chart 300 depicting relative resistance changes as increasing strains, from 0% to 4000%, are applied to two embodiments of the stretchable electrical interconnect 102. The chart 300 indicates that the stretchable electrical interconnect 102 sustains its electrical performance under substantial strain.

FIG. 4 shows a chart 400 illustrating relative resistance changes of the stretchable electrical interconnect 102 during cyclic stretching between ε=0% and ε=3000% over 20,000 cycles. The chart 400 demonstrates long-term repeatability and durability of the stretchable electrical interconnect 102.

FIG. 5A shows a flow chart 500 illustrating a method of fabricating the flexible electronic system 104, according to an embodiment.

FIG. 5B shows a flow chart 550 illustrating a method of fabricating the flexible electronic system 104, according to another embodiment.

FIG. 6A illustrates the structural and material details of an embodiment of the flexible electronic system 600, in which one or more electronic devices include an array of 8×8 LED chips.

FIG. 6B depicts a 3D schematic 650 of the embodiment of the flexible electronic system 600.

FIG. 7A shows a photograph of the flexible electronic system 700, in which the flexible electronic system 700 is an 8×8 LED array connected by the stretchable electrical interconnects 102.

FIG. 7B is a scanning electron microscope (SEM) image showing the stretchable electrical interconnects 102 between functional island nodes, (in this embodiment, LED chips) in the flexible electronic system 700.

FIG. 7C provides a magnified image of part of the stretchable electrical interconnects 102 from FIG. 7B.

FIG. 7D shows a photograph of the flexible electronic system 700 wrapped around a finger.

FIGS. 7E and 7F show the flexible electronic system 700 being bent in different directions while maintaining its structural integrity and electrical properties, due to the stretchable electrical interconnects 102.

FIG. 8 shows an embodiment of a conformal vacuum transfer printing (CVTP) method 800 for transferring a flexible electronic system onto a curved surface. The method 800 may be performed once the flexible electronic system 104 is fabricated in planar form in accordance with the method 500 illustrated in FIG. 5A.

FIG. 9A shows an embodiment of the flexible electronic system 900 conformed to a hemispherical surface, fabricated according to the methods exemplified in FIGS. 5A, 5B, and/or FIG. 8. In this embodiment, the flexible electronic system 900 is an 8×8 LED array connected by the stretchable electrical interconnects 102. FIG. 9D shows a partially magnified view of the flexible electronic system 900, while FIG. 9G shows the system with all LEDs lit.

FIG. 9B shows an embodiment of the flexible electronic system 910 conformed to a saddle-shaped surface, fabricated according to the methods exemplified in FIGS. 5A, 5B, and/or FIG. 8. The flexible electronic system 910 is also an 8×8 LED array connected by the stretchable electrical interconnects 102. FIG. 9E shows a partially magnified view of the flexible electronic system 910.

FIG. 9C shows an embodiment of the flexible electronic system 920 conformed to an irregular curved surface, fabricated according to the methods exemplified in FIGS. 5A, 5B, and/or FIG. 8. In this embodiment, the flexible electronic system 920 is an 8×8 LED array connected by the stretchable electrical interconnects 102. FIG. 9F shows a partially magnified view of the flexible electronic system 920.

FIGS. 9H, 9I, 9J, 9K, and 9L present embodiments of flexible electronic systems, where LED chips form the letters H, K, U, S, and T, respectively.

FIGS. 10A and 10B show Finite Element Analysis (FEA) simulation results 1000a and 1000b depicting stress distribution in the flexible electronic system 900 when conformed to a hemispherical surface.

FIGS. 10C and 10D show FEA simulation results 1000c and 1000d depicting stress distribution in the flexible electronic system 910 when conformed to a saddle-shaped surface.

Skilled artisans will appreciate that elements in the figures are illustrated for simplicity and clarity and have not necessarily been depicted to scale. For example, the dimensions of some of the elements in the illustrations, block diagrams or flowcharts may be exaggerated in respect to other elements to help to improve understanding of the present embodiments.

### DETAILED DESCRIPTION

Embodiments of the present invention will be described, by way of example only, with reference to the accompanying drawings. Like reference numerals and characters used in the drawings correspond to like elements or equivalents throughout.

The present disclosure provides a stretchable electrical interconnect and flexible electronic systems incorporating flexible and stretchable interconnects that maintain structural integrity and electrical performance under varying elongation, bending, and conformational conditions on curved surfaces. The disclosed embodiments enable the development of flexible electronic systems (interchangeably referred to as “curved electronics”) for flexible applications such as wearable electronics, soft robotics, and flexible displays.

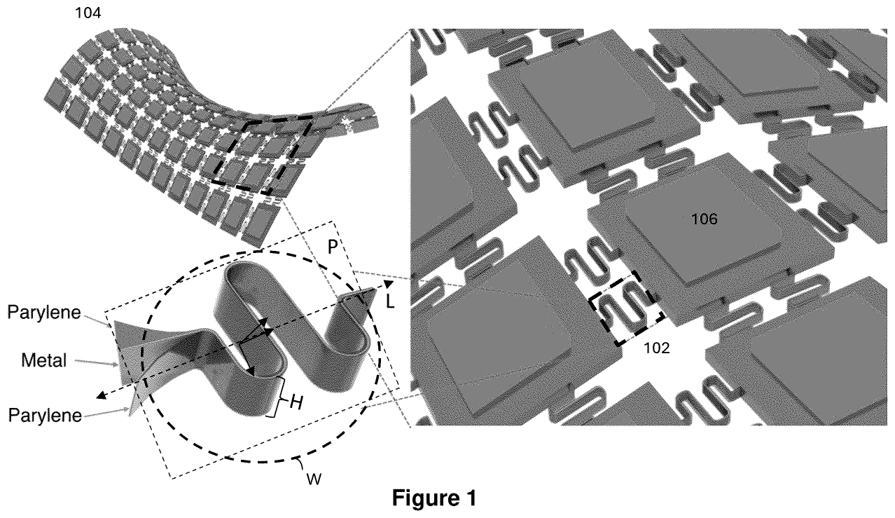

FIG. 1 illustrates a schematic diagram 100 of an embodiment of a stretchable electrical interconnect 102. This figure also depicts an embodiment of a flexible electronic system 104, which incorporates the stretchable electrical interconnect 102.

In this embodiment, the stretchable electrical interconnect 102 includes a curved wall W that is stretchable lengthwise L towards its two ends. As shown in FIG. 1, the curved wall W has a height H extending perpendicularly from a plane P defined by the two ends of the wall. These ends are configured to connect to one or more electronic devices 106. The stretchable properties of the curved wall W allow it to conform to non-planar geometries, beneficial in applications requiring adaptability to dynamic or complex surfaces.

The perpendicular height H of the curved wall W enables 3D bending, both out-of-plane relative to plane P and in-plane. This three-dimensional flexibility enhances the versatility of the stretchable electrical interconnect 102, allowing it to adapt to a wide range of surface topologies, such as convex or concave surfaces, while maintaining electrical and mechanical performance.

The height H imparts a 3D geometry to the curved wall W. In some embodiments, the 3D geometry is serpentine, providing enhanced stretchability by evenly distributing mechanical strain across the structure. This design minimizes stress concentrations at arc regions during deformation, thereby improving the mechanical and electrical properties of the interconnect compared to in-plane serpentine structures known in the art. It will be understood by those skilled in the art that the curved wall W is not limited to a serpentine geometry; any 3D structure incorporating curved regions to achieve flexibility and stretchability is contemplated.

When the stretchable electrical interconnect 102 is applied on a flat surface, the plane P is horizontal, and the perpendicular curved wall W is vertically arranged, resulting in a vertical serpentine geometry. The vertical serpentine structure allows the height H of the wall to extend vertically relative to plane P. In such embodiments, the interconnect 102 may be referred to as a vertical serpentine conductor (VSC), and the associated flexible electronic system 104 as a VSC-interconnected functional device.

It will be understood by those skilled in the art that when applied to curved surfaces, plane P may not be horizontal, and the perpendicular arrangement of the curved wall W may not be strictly vertical.

The curved wall W has a thickness comprising a conductive metal layer sandwiched between two insulating polymer layers. The polymer layers, preferably made of parylene (e.g., Parylene C), provide flexibility, durability, and uniformity. The metal layer is strategically positioned near the mechanical neutral plane to minimize strain during mechanical deformation, thus improving durability and reducing material fatigue.

In certain embodiments, the vertical serpentine geometry of the interconnect 102 has a curve radius of 30 micrometers (μm) at arc regions, with a height H of 50 μm. This configuration balances mechanical flexibility with electrical conductivity, ensuring that the interconnect 102 can withstand repeated mechanical stresses without performance degradation. It will be understood by those skilled in the art that variations in radii or heights may be implemented to meet specific application requirements, without sacrificing flexibility or conductivity.

The stretchable electrical interconnect 102 is integral to the flexible electronic system 104. As exemplified in FIG. 1, the system 104 comprises one or more electronic devices 106 connected by the interconnects 102. Each interconnect features the curved wall structure, allowing the system to conform to various curved surfaces while maintaining electrical connectivity. This is particularly advantageous for applications like wearable electronics, where the system must adapt to the contours of a user's body or other dynamic surfaces.

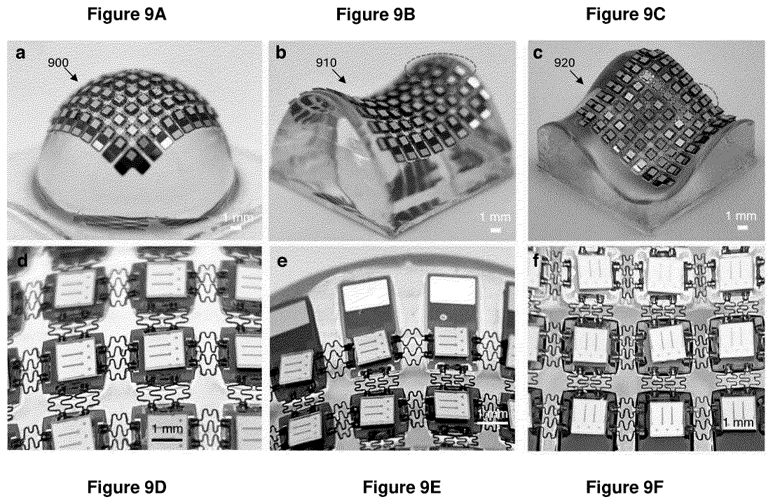

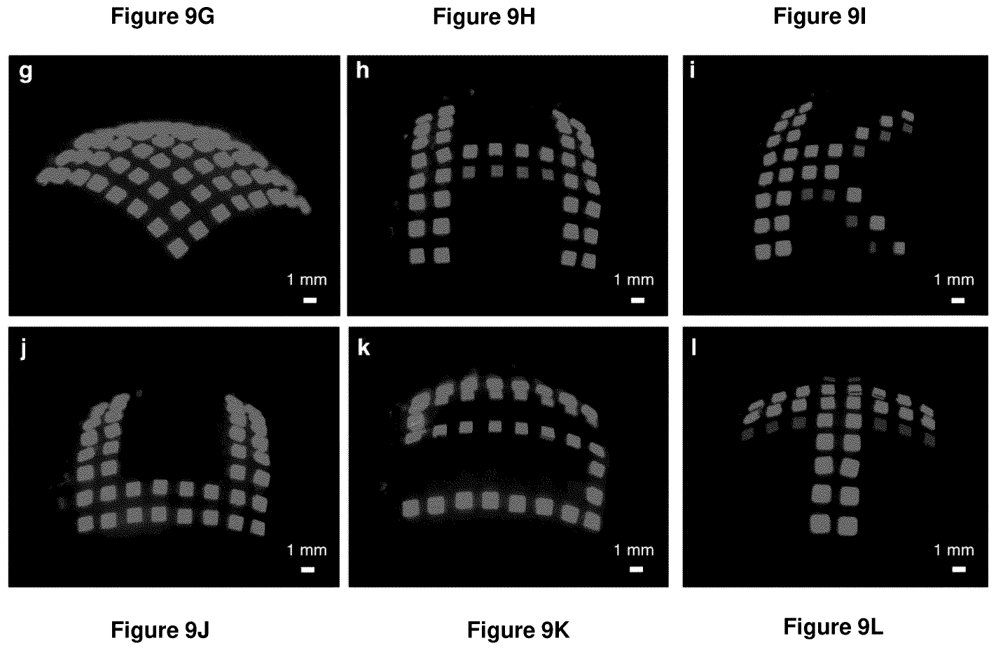

In some embodiments, the flexible electronic system 104 is designed for application on curved surfaces such as spherical or saddle-shaped substrates. The system's ability to stretch, bend, and conform without compromising electrical performance makes it highly suited for a variety of applications, including wearable electronics, soft robotics, flexible displays, and energy-harvesting devices. Due to these properties, flexible electronic systems are also referred to as bendable or curvable electronic systems. FIGS. 9A through 9L depict examples of such applications. That is, when applied to curved surfaces, the flexible electronic system 104 conforms to the curvature of the surface, thereby becoming a curved system. It will be understood by those skilled in the art that when applied to a flat surface, the flexible electronic system 104 may not exhibit any curvature and may remain flat.

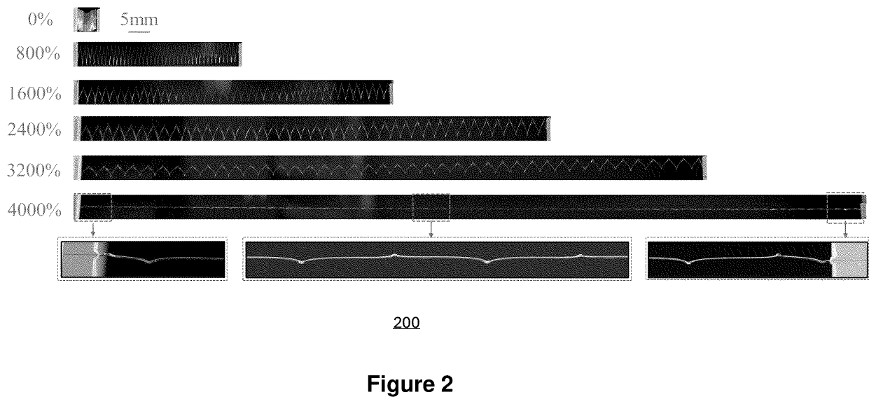

FIG. 2 illustrates a series of images depicting the stretchable electrical interconnect 102 under various stretching conditions, ranging from 0% to 4000% elongation. The images demonstrate that the interconnect 102 retains its structural integrity even under significant elongation.

In this embodiment, the stretchable electrical interconnect 102 has an initial length of 5 millimeters (mm) and exhibits exceptional stretchability, retaining its structural integrity at elongation levels of 800%, 1600%, 2400%, 3200%, and up to 4000% of its original length. This degree of stretchability is especially beneficial for applications that require the interconnect to withstand large mechanical deformations, such as wearable electronics, where both flexibility and durability are critical for reliable operation.

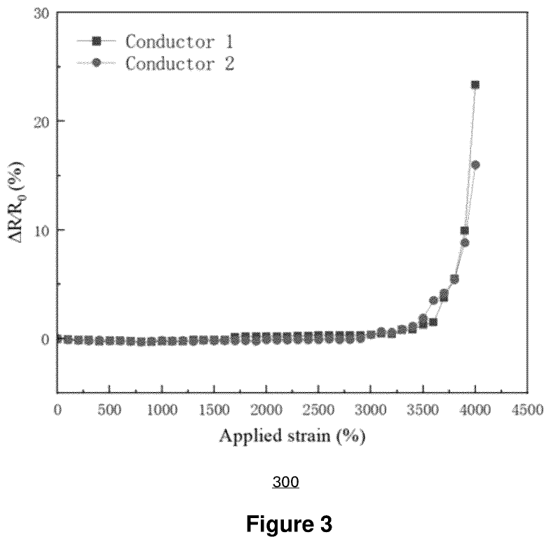

FIG. 3 provides a chart 300 that illustrates the relative resistance changes of two embodiments of the stretchable electrical interconnect 102 when subjected to increasing strain, from 0% to 4000%.

In chart 300, the two interconnects are labeled as Conductor 1 and Conductor 2. Their relative resistance changes are represented by square and circular markers, respectively, under applied strains of 0%, 200%, 1000%, 1500%, 2000%, 2500%, 3000%, 3500%, and 4000%. The results indicate that the stretchable electrical interconnect 102 maintains its electrical performance even under significant strain.

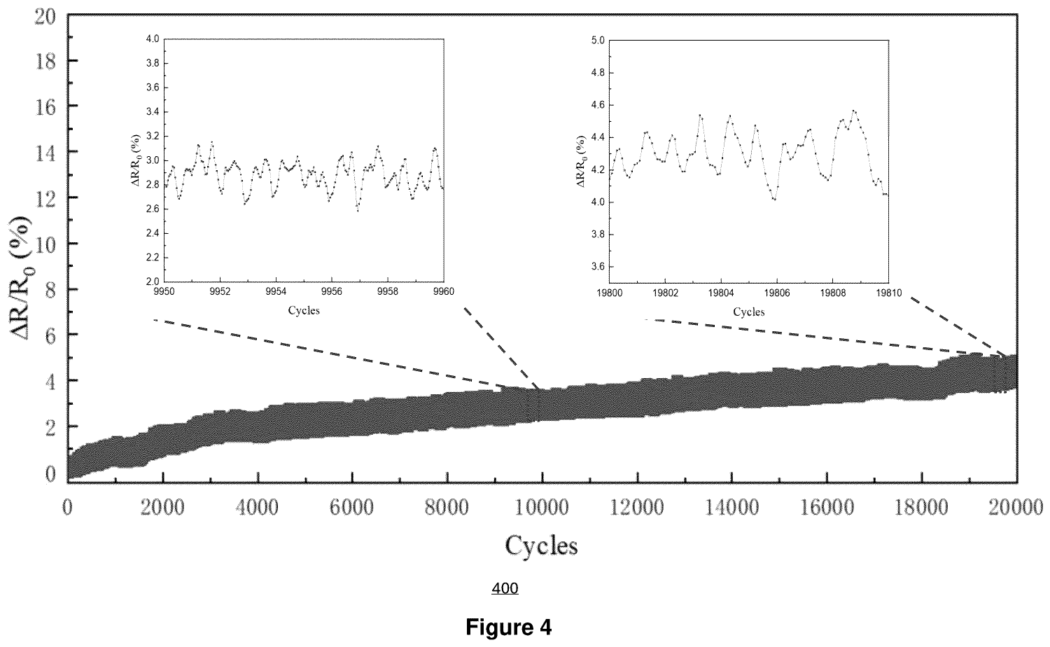

FIG. 4 depicts a chart 400 illustrating the relative resistance changes of the stretchable electrical interconnect 102 during cyclic stretching between 0% and 3000% strain over 20,000 cycles. The chart demonstrates the long-term durability and repeatability of the interconnect 102.

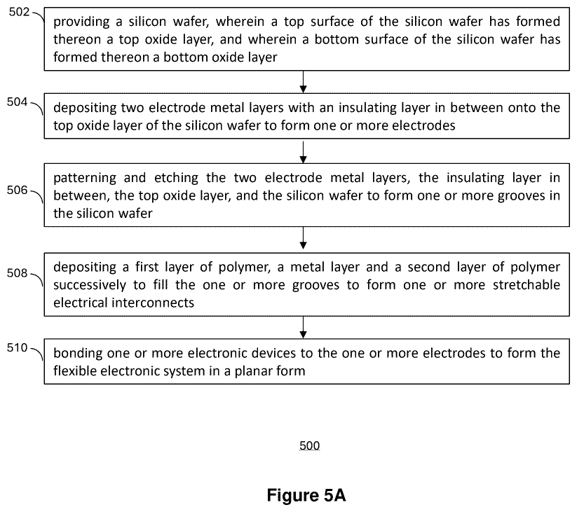

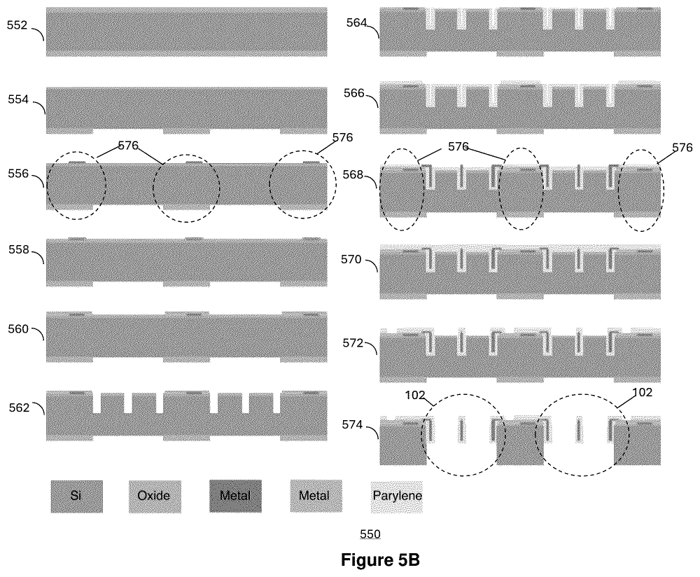

The flexible electronic system 104 can be fabricated using various methods. For example, FIG. 5A illustrates a flowchart of a method 500 for fabricating the system 104, according to one embodiment. The method 500 employs a silicon-based Micro-Electro-Mechanical Systems (MEMS) fabrication process.

Step 502 of the method 500 includes providing a silicon wafer, wherein a top surface of the silicon wafer has formed thereon a top oxide layer, and wherein a bottom surface of the silicon wafer has formed thereon a bottom oxide layer.

Step 504 involves depositing two electrode metal layers with an insulating layer in between onto the top oxide layer of the silicon wafer to form one or more electrodes.

Step 506 involves patterning and etching the two electrode metal layers, the insulating layer in between, the top oxide layer, and the silicon wafer to form one or more grooves in the silicon wafer.

In step 508, the method 500 involves depositing a first layer of polymer, a metal layer and a second layer of polymer successively to fill the one or more grooves to form one or more stretchable electrical interconnects. As described above, each interconnect comprises a curved wall that is stretchable lengthwise with its height extending perpendicularly to the plane of the two ends of the wall. The two ends are configured to connect to electronic devices.

Step 510 involves bonding one or more electronic devices to the one or more electrodes to form the flexible electronic system in a planar form.

In some embodiments, prior to step 504, the method 500 can comprise a step of patterning the bottom oxide layer to dispose one or more areas of the bottom surface of the silicon wafer.

In certain embodiments, the method 500 further includes:
fetching the flexible electronic system using a thin polymer film, wherein an edge of the thin polymer film is secured by an acrylic ring; and
printing the flexible electronic system onto a curved surface within a vacuum chamber, wherein the edge of the thin polymer film is brought into close contact with the vacuum chamber and the remaining portion of the thin polymer film is stretched to transfer the flexible electronic system onto the curved surface.

As described above, the method 500 begins with the preparation of a silicon wafer, which is treated to form oxide layers on both surfaces. In some embodiments, the bottom oxide layer is patterned to act as a mask for subsequent etching processes. Metal electrode layers are deposited onto the top oxide layer with an insulating layer between them to form electrodes.

The electrodes, insulating layer, top oxide layer, and silicon wafer are patterned and etched to create grooves. These grooves are filled by sequentially depositing a first polymer layer, a metal layer, and a second polymer layer to form the stretchable interconnects. The final step involves bonding electronic devices to the electrodes, resulting in a planar flexible electronic system with stretchable interconnects.

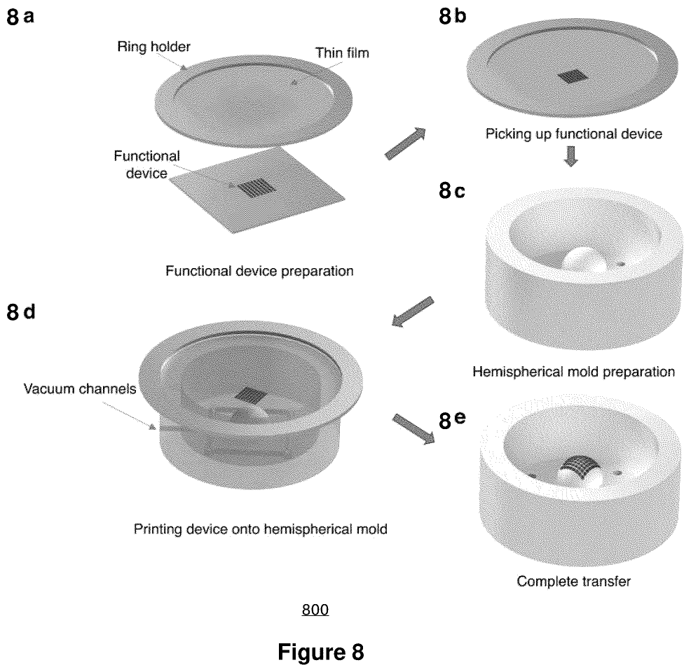

After the fabrication of the planar system, it can be transferred to a curved surface using conformal vacuum transfer printing (CVTP). An exemplary CVTP method 800 is depicted in FIG. 8, which transfers the flexible system onto curved surfaces via a polymer film stretched within a vacuum chamber.

FIG. 5B depicts a flowchart of another MEMS fabrication method 550 for producing the flexible electronic system 104, employing double-sided polished silicon wafers with 3-micron-thick thermal oxide on both sides.

In step 552, the silicon wafer is prepared with oxide layers on both surfaces, while step 554 employs photolithography to pattern the oxide layer on the reverse side, which serves as a mask for subsequent etching processes. The photolithography process involves depositing adhesion promoters, spin-coating photoresist, UV exposure, developing, and hard baking.

Thereafter, the reverse-side silicon oxide layer is etched using a dry etching process. O2 plasma is applied to remove any remaining photoresist.

Step 556 includes the deposition and patterning of a bottom electrode metal layer onto the front side of the silicon wafer. The deposition is performed at a high sputtering rate, followed by patterning via photolithography and wet etching.

A thin silicon dioxide insulating layer is deposited between the metal layers in step 558, using a plasma-enhanced chemical vapor deposition (PECVD) process at high deposition rates.

The second electrode metal layer is deposited and patterned on top of the insulating layer in step 560.

In step 562, three-dimensional deep trenches are etched into the silicon wafer to form the stretchable interconnects. Photolithography, dry etching, and deep reactive ion etching (DRIE) processes are employed to create grooves with highly anisotropic profiles.

Step 564 involves depositing a first Parylene-C layer onto the wafer's front side. A surface treatment process promotes adhesion between the silicon wafer and the Parylene-C layer, ensuring uniform deposition.

A spray-coated photoresist layer is applied as a masking layer for subsequent metal layer openings, followed by exposure, developing, and etching processes in step 566.

Step 568 involves the deposition of an additional metal layer to interconnect the island nodes 576. In step 570, a second Parylene-C layer is deposited and patterned in step 572 to encapsulate and protect the internal functional layers. In silicon-based MEMS fabrication, an “island” refers to discrete, isolated regions of material that are structurally independent from the surrounding substrate. These islands, also referred to as island nodes 576 in the present application, serve as electrical functional areas for bonding and packaging electronic devices, such as LED chips, in the flexible electronic system 104.

Thereafter, in step 574, the silicon wafer is dry-etched from the backside. The oxide layer patterned in step 554 serves as a mask during this etching process. Both Deep Reactive Ion Etching (DRIE) and Reactive Ion Etching (RIE) systems are employed for this step to release the stretchable electrical interconnects 102 and the interconnected island nodes 576. During this process, the silicon substrate is also thinned to enhance the flexibility of the system. The DRIE process is performed with alternating passivation and etching cycles, which provide a highly anisotropic etch, ensuring the structural integrity of the interconnects while minimizing lateral undercut.

While not shown in FIG. 5B, manual flip-chip bonding tools, such as the FINEPLACER 96 “Lambda”, may be employed to pick and place LED chips (30 mil×30 mil) onto the island nodes 576. During this process, low-temperature solder paste is used to maintain the mechanical properties of the Parylene-C layer while ensuring proper electrical connectivity.

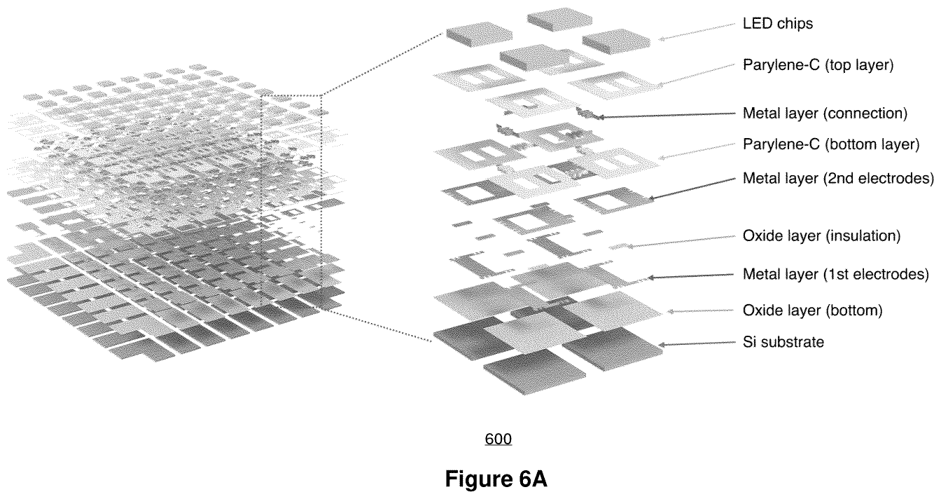

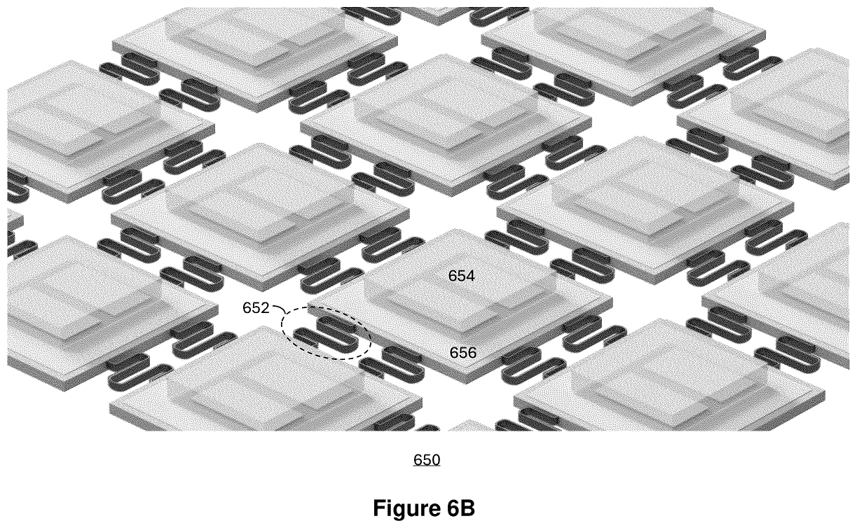

FIG. 6A provides a detailed illustration of the structural composition of the flexible electronic system 600, showing an array of 8×8 LED chips interconnected by the stretchable electrical interconnects 652. FIG. 6B shows a 3D schematic 650 of the flexible electronic system 600, demonstrating how the stretchable electrical interconnects 652 enable the system to conform to curved surfaces while maintaining electrical performance.

The flexible electronic system 600, as shown in FIG. 6A, is constructed from functional silicon island nodes interconnected by the stretchable electrical interconnects 652. These island nodes serve as bonding sites for the 8×8 LED chips, forming an LED array display device. The interconnects 652 provide mechanical flexibility and are designed to maintain electrical conductivity, even under mechanical stress. FIG. 6A also highlights the material composition and structural layering of the 8×8 LED array device, illustrating the functional elements that enable its curvability and reliability.

As described in step 556 and depicted in FIG. 5B, the fabrication process involves forming silicon islands 576, 656, which serve as functional vehicles for housing the electronic devices. These islands, or island nodes, can also be referred to as silicon-based functional vehicles. Photolithography and etching processes are used to define the oxide layer as a mask on the backside of the wafer. The passive matrix configuration of the LED array allows for individual control of the LEDs, with three metal layers forming the anodes, cathodes, and electrical interconnections between the island nodes.

After electrode pads for the LEDs are defined on the silicon islands, grooves approximately 10 μm wide and 40 to 50 μm deep are patterned using DRIE to create the stretchable electrical interconnects 102, 652 between island nodes 576, 656. The grooves are filled by depositing successive layers of Parylene-C, metal, and Parylene-C. The first Parylene-C layer is deposited at the bottom, while the metal layer is positioned near the neutral mechanical plane to improve mechanical robustness. The second Parylene-C layer is then deposited to encapsulate the metal and protect the interconnect. Photolithography and reactive-ion etching (RIE) are used to define and pattern both Parylene-C and oxide layers.

DRIE and RIE are then employed sequentially to etch the silicon from the backside of the wafer, releasing the stretchable electrical interconnects 102, 652 and the interconnected silicon-based functional vehicles 656.

Once the interconnects 652 have been released, LED chips 654 are bonded to the electrode pads on the island nodes 656 using pick-and-place techniques, ensuring precise alignment and connectivity.

FIG. 6B shows a 3D schematic 650 of the silicon-based functional vehicles (island nodes) 656, each bonded with LED chips 654. Multiple stretchable electrical interconnects 652 are used to connect the island nodes 656. In this embodiment, the interconnects 652 are designed with redundancy to improve system reliability. These interconnects can also function as data connections for more complex circuits in future applications.

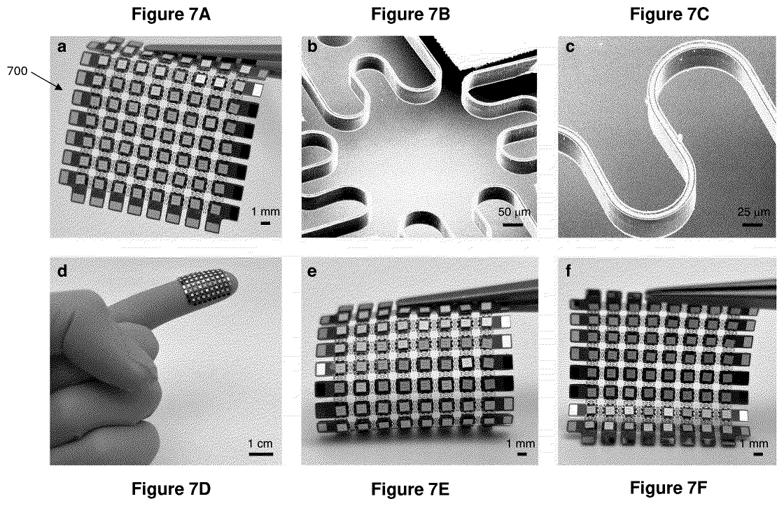

FIG. 7A provides a photograph of the flexible electronic system 700, which features a 22 mm×22 mm display comprising an 8×8 LED array connected by stretchable electrical interconnects 102.

FIG. 7B is a scanning electron microscope (SEM) image showing the stretchable electrical interconnects 102 between functional island nodes in the flexible electronic system 700, with LED chips (Bridgelux BXDA, 40 mil×40 mil) bonded thereon. FIG. 7C provides a magnified view of the stretchable interconnects 102. FIG. 7D shows a photograph of the flexible electronic system 700 wrapped around a finger. FIGS. 7E and 7F illustrate the system being bent in various directions, demonstrating its ability to maintain structural integrity and electrical properties during significant deformation.

As depicted in FIGS. 7A through 7F, the flexible electronic system 700 is capable of functioning on a variety of curved surfaces. The stretchable electrical interconnects ensure that electrical performance is maintained even under substantial bending and stretching. For example, FIG. 7D demonstrates the system's adaptability when wrapped around a finger, highlighting its suitability for irregular surfaces while maintaining full functionality.

The flexible electronic system 700, enabled by the stretchable electrical interconnects 102 and 652, provides a robust and flexible solution for applications where electronics need to conform to dynamic and complex surfaces. This is particularly beneficial for wearable devices and other applications that require durability and flexibility to maintain performance during continuous movement and deformation.

FIG. 8 illustrates an embodiment of a conformal vacuum transfer printing (CVTP) method 800 for transferring a flexible electronic system onto a curved surface. This method is applied after the flexible electronic system 104, 700 has been fabricated in planar form, as described in methods 500 and 550 (FIGS. 5A and 5B). In this embodiment, the flexible electronic system 104, 700 is referred to as a functional device.

In some embodiments, a thin polymer film is used to pick up the flexible electronic system 104, 700 (step 8b) and transfer it onto a curved substrate within a vacuum chamber (step 8d). The polymer film is stretched during the transfer process to ensure accurate placement of the flexible electronic system 104, 700 onto the curved surface, minimizing distortion or misalignment.

In the exemplified CVTP method 800, the flexible electronic system 104, 700 is picked up from a planar substrate using a thin polymer film, whose edge is secured by an acrylic ring. As shown in step 8a, the process begins after the fabrication of flexible electronic systems 104, 700, which can be manufactured using silicon-based MEMS fabrication technology, as depicted in methods 500 and 550.

During the picking-up process as depicted in step 8b, the thin polymer film is fastened to the ring holder, allowing for controlled movement. The thin film is gently lowered until it makes complete contact with the flexible electronic system 104, 700, enabling the system to be picked up from the substrate.

In step 8d, the flexible electronic system 104, 700 is transferred onto a curved surface inside a customized vacuum chamber. Air channels integrated into the chamber allow for uniform stretching of the polymer film, ensuring the accurate and smooth placement of the flexible electronic system onto the curved mold. Once the system is entirely in contact with the curved surface, the vacuum chamber is vented, resulting in the flexible electronic system remaining on the curved surface, aided by adhesion to the treated surface (e.g., using uncured polydimethylsiloxane (PDMS)).

This CVTP method 800 provides an efficient and reliable way to transfer flexible electronics onto non-planar surfaces. It ensures that the functional integrity of the system is maintained after the transfer process, making it ideal for high-precision applications, such as biomedical devices, where conformity to complex surfaces is critical.

By virtue of the CVTP method, according to some embodiments, as illustrated in FIGS. 9A-9C, flexible electronic systems 900, 910, 920 can be applied to a variety of curved surfaces, including hemispherical, saddle-shaped, and irregular surfaces. Detailed views in FIGS. 9D-9F show how the stretchable electrical interconnects allow the system to maintain its structural and electrical integrity when conformed to different surface geometries. As shown in FIG. 9A, the LED array is wrapped intimately onto the curved surface, and the magnified image in FIG. 9D reveals different deformation of the stretchable electrical interconnects 102 in the center region to fit the curved surface better.

In FIG. 9D, the stretchable electrical interconnects 102 in the middle area are in a stretched status, while the stretchable electrical interconnects 102 in the surrounding parts show a state of compression. The stress generated on these non-planar surfaces is alleviated by the 3D bending or dual bending capability rendered by the curved walls, which allows both out-of-plane bending (relative to the plane defined by the two ends of the walls) and in-plane bending. This dual bending ability enables the flexible electronic systems described in the present application to conform to a wide range of complex surface geometries. This adaptability makes the present invention particularly suitable for flexible displays, wearable electronics, and other applications where devices must conform to dynamic surfaces while maintaining consistent performance.

The saddle-shaped display (FIGS. 9B and 9E) and the irregular curved display (FIG. 9C and FIG. 9F) are also presented to demonstrate the conformability of the flexible electronic systems and the feasibility of the CVTP technology. The electronic devices (in this embodiment, LED arrays) can be configured with a passive matrix to drive each device/chip individually and display designed patterns. FIG. 9G demonstrates the system in operation, with all LEDs on the hemispherical surface illuminated, while FIGS. 9H, 9I, 9J, 9K, and 9L depict different configurations of the LED array forming specific letters and patterns such as H, K, U, S, and T, respectively.

As exemplified in FIGS. 9A, 9B and 9C, three different concave curved molds can be manufactured through a 3D printer, including a hemispherical mold with a 2.5 cm diameter, a saddle surface mold with a 2.5 cm diameter curvature at the saddle point, and an irregular curved surface with dimension of 2.5 cm×2.5 cm. The corresponding convex curved substrates can be fabricated using a demolding process.

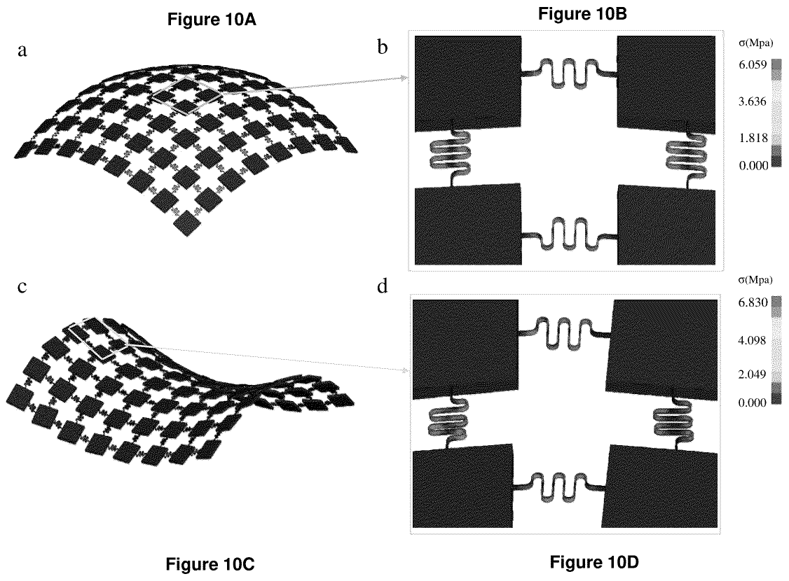

FIGS. 10A and 10B show Finite Element Analysis (FEA) simulation results 1000a and 1000b, depicting the stress distribution in the flexible electronic system 900 when conformed to a hemispherical surface. These results demonstrate that the system can maintain mechanical and electrical performance under deformation.

FIGS. 10C and 10D present FEA simulation results 1000c and 1000d for the flexible electronic system 910 when applied to a saddle-shaped surface. The stress distribution analysis confirms that the system can conform to the surface while maintaining its structural integrity.

The simulations indicate that the maximum stress occurs at the stretchable electrical interconnects in the central region of the hemispherical surface, with a value of 6.1 MPa (FIG. 10B). For the saddle surface, the maximum stress is observed at the edges, reaching 6.8 MPa (FIG. 10D). These stress values are significantly lower than the tensile strength of copper (approximately 210 MPa), confirming that the stretchable interconnects effectively manage stress concentration, enhancing the overall reliability of the flexible electronic system under mechanical deformation.

The present invention provides a robust and flexible solution for stretchable and flexible electronic systems, combining mechanical adaptability with reliable electrical performance. The stretchable electrical interconnect technology described herein addresses the challenges of applying electronics to dynamic and irregular surfaces, paving the way for next-generation electronics in various applications, including flexible displays, wearable devices, and soft robotics.

It will be appreciated by those skilled in the art that numerous variations and modifications may be made to the present invention without departing from the scope of the invention as broadly described. The embodiments presented herein are, therefore, illustrative and not restrictive.

What is claimed is:

1. A stretchable electrical interconnect, comprising:
a curved wall that is stretchable lengthwise towards two ends of the curved wall,
wherein the curved wall has a height that extends perpendicularly to a plane in which the two ends of the curved wall extend, and
wherein the two ends of the curved wall are configured to be connectable to one or more electronic devices.

2. The stretchable electrical interconnect of claim 1, wherein the curved wall has a vertical serpentine geometry, and the height of the curved wall extends vertically relative to the plane in which the two ends of the curved wall extend.

3. The stretchable electrical interconnect of claim 1, wherein the curved wall comprises a thickness, the thickness including a metal layer sandwiched between two polymer layers.

4. The stretchable electrical interconnect of claim 3, wherein the two polymer layers comprise parylene.

5. The stretchable electrical interconnect of claim 3, wherein the metal layer is situated near a mechanical neutral plane.

6. The stretchable electrical interconnect of claim 1, wherein when conformed to a curved surface, the curved wall is configured to be bendable out-of-plane relative to the plane in which the two ends of the curved wall extend.

7. The stretchable electrical interconnect of claim 1, wherein the curved wall is configured to be bendable in-plane relative to the plane in which the two ends of the curved wall extend.

8. The stretchable electrical interconnect of claim 1, wherein the curved wall is configured to be stretchable up to 4000% of its original length while maintaining structural integrity and electrical performance.

9. The stretchable electrical interconnect of claim 2, wherein the vertical serpentine geometry has a radius of 30 micrometers (μm) and a height of 50 micrometers (μm).

10. A flexible electronic system, comprising:
one or more electronic devices, and
one or more stretchable electrical interconnects connecting the one or more electronic devices,
wherein each of the one or more stretchable electrical interconnects comprises:
a curved wall that is stretchable lengthwise towards two ends of the curved wall,
wherein the curved wall has a height that extends perpendicularly to a plane in which the two ends of the curved wall extend, and
wherein the two ends of the curved wall are connected to the one or more electronic devices.

11. The flexible electronic system of claim 10, wherein the curved wall has a vertical serpentine geometry, and the height of the curved wall extends vertically relative to the plane in which the two ends of the curved wall extend.

12. The flexible electronic system of claim 10, wherein the curved wall comprises a thickness, the thickness including a metal layer sandwiched between two polymer layers.

13. The flexible electronic system of claim 12, wherein the two polymer layers comprise parylene.

14. The flexible electronic system of claim 12, wherein the metal layer is situated near a mechanical neutral plane.

15. The flexible electronic system of claim 10, wherein when the flexible electronic system is conformed to a curved surface, the curved wall is configured to be bendable out-of-plane relative to the plane in which the two ends of the curved wall extend.

16. The flexible electronic system of claim 10, wherein the curved wall is configured to be bendable in-plane relative to the plane in which the two ends of the curved wall extend.

17. The flexible electronic system of claim 10, wherein the curved wall is configured to be stretchable up to 4000% of its original length while maintaining structural integrity and electrical performance.

18. The flexible electronic system of claim 11, wherein the vertical serpentine geometry has a radius of 30 micrometers (μm) and a height of 50 micrometers (μm).

19. A method of fabricating a flexible electronic system, the method comprising:
providing a silicon wafer, wherein a top surface of the silicon wafer has formed thereon a top oxide layer, and wherein a bottom surface of the silicon wafer has formed thereon a bottom oxide layer;
depositing two electrode metal layers with an insulating layer in between onto the top oxide layer of the silicon wafer to form one or more electrodes;
patterning and etching the two electrode metal layers, the insulating layer in between, the top oxide layer, and the silicon wafer to form one or more grooves in the silicon wafer;
depositing a first layer of polymer, a metal layer and a second layer of polymer successively to fill the one or more grooves to form one or more stretchable electrical interconnects; and
bonding one or more electronic devices to the one or more electrodes to form the flexible electronic system in a planar form,
wherein each of the stretchable electrical interconnects is a curved wall that is stretchable lengthwise towards two ends of the curved wall,
wherein the curved wall has a height that extends perpendicularly to a plane in which the two ends of the curved wall extend, and
wherein the two ends of the curved wall are connected to the one or more electronic devices.

20. The method of claim 19, further comprising:
fetching the flexible electronic system using a thin polymer film, wherein an edge of the thin polymer film is secured by an acrylic ring; and
printing the flexible electronic system onto a curved surface within a vacuum chamber, wherein the edge of the thin polymer film is brought into close contact with the vacuum chamber and the remaining portion of the thin polymer film is stretched to transfer the flexible electronic system onto the curved surface.
